(19) United States
(12) Patent Application Publication
(10) Pub. No.: US 2025/0297143 A1
(43) Pub. Date: Sep. 25, 2025

(54) CURABLE RESIN COMPOSITION, CURABLE FILM, AND LAMINATED FILM

(71) Applicant: Resonac Corporation, Tokyo (JP)

(72) Inventors: Yohei OHKODA, Tokyo (JP); Takeshi MASAKI, Tokyo (JP); Takashi KAWAMORI, Tokyo (JP)

(21) Appl. No.: 18/860,281

(22) PCT Filed: Jul. 10, 2023
(86) PCT No.: PCT/JP2023/025467

§ 371 Date: Oct. 25, 2024

(30) Foreign Application Priority Data
Jul. 12, 2022 (JP) 2022-111965

(51) Int. Cl. C09J 7/38

(52) U.S. Cl. CPC C09J 7/387; C09J 2203/326; C09J 2301/414

(57) ABSTRACT

A curable resin composition contains: a rubber component (A); a cross-linking component having an epoxy group (B); an ester-based curing agent (C); and a curing accelerator (D).

### TECHNICAL FIELD

The present disclosure relates to a curable resin composition, a curable film, and a laminated film.

### BACKGROUND ART

In recent years, with an increase in the speed of a transmission signal in a printed wiring board, the high frequency of the signal has been progressed. Along with this progress, the printed wiring board is increasingly required to have low dielectric properties (low dielectric constant and low dissipation factor) in a high frequency region. In addition, a protective layer (coverlay) covering a circuit of a printed wiring board, an interlayer adhesive in a multilayer printed wiring board, and the like are also required to have low dielectric properties in addition to having adhesiveness with a base material and the like. As a resin composition from which a cured product having low dielectric properties can be obtained, for example, Patent Literature 1 proposes an adhesive composition containing a styrene-based elastomer.

### CITATION LIST

### Patent Literature

Patent Literature 1: Japanese Unexamined Patent Publication No. 2018-150543

### SUMMARY OF INVENTION

### Technical Problem

However, the cured product formed from the adhesive composition described in Patent Literature 1 does not have sufficient low dielectric properties in a high frequency region, and there is room for further improvement.

The present disclosure has been made in view of the above circumstances, and an object of the present disclosure is to provide a curable resin composition capable of forming a cured product excellent in low dielectric properties in a high frequency region while having adhesiveness to an adherend, a curable film using the curable resin composition, and a laminated film.

### Solution to Problem

In order to solve the above-described problems, the present disclosure provides the following curable resin composition, curable film, and laminated film.

[1] A curable resin composition containing: a rubber component (A); a cross-linking component having an epoxy group (B); an ester-based curing agent (C); and a curing accelerator (D).

[2] The curable resin composition according to [1], in which the curable resin composition is used for formation of a protective layer covering an electric circuit.

[3] The curable resin composition according to [1] or [2], in which the cross-linking component (B) having the epoxy group has a weight average molecular weight of 200 to 1000.

[4] The curable resin composition according to any one of [1] to [3], in which a content of the curing accelerator (D) is 0.1 to 10 parts by mass with respect to 100 parts by mass of a total amount of the rubber component (A), the cross-linking component having the epoxy group (B), and the ester-based curing agent (C).

[5] A curable film including the curable resin composition according to any one of [1] to [4].

[6] A laminated film including: a base material film; and the curable film according to [5] provided on the base material film.

### Advantageous Effects of Invention

According to the present disclosure, it is possible to provide a curable resin composition capable of forming a cured product excellent in low dielectric properties in a high frequency region while having adhesiveness to an adherend, a curable film using the curable resin composition, and a laminated film.

### DESCRIPTION OF EMBODIMENTS

Hereinafter, some embodiments of the present disclosure will be described in detail. However, the present disclosure is not limited to the following embodiments.

In the present specification, a numerical range indicated using “to” indicates a range including numerical values described before and after “to” as a minimum value and a maximum value, respectively. In the numerical range described in stages in the present specification, an upper limit value or a lower limit value of a numerical range of a certain stage may be replaced with an upper limit value or a lower limit value of a numerical range of another stage. In addition, in the numerical range described in the present specification, the upper limit value or the lower limit value of the numerical range may be replaced with a value shown in examples. When referring to the amount of each component in the composition in the present specification, if there are a plurality of substances corresponding to each component in the composition, it means the total amount of the plurality of substances present in the composition unless otherwise specified. “A or B” only needs to include either A or B, and may include both A and B. A “solid content” refers to a nonvolatile content excluding a volatile substance (water, solvent, and the like) in a resin composition. That is, the “solid content” refers to a component other than a solvent that remains without being volatilized in drying of the resin composition, to be described later, and also includes a component in the form of a liquid, syrup, or a wax at room temperature (25° C.). In the present specification, for example, “(meth) acrylic acid” means “acrylic acid” and “methacrylic acid” corresponding thereto, and the same applies to other similar words.

### [Curable Resin Composition]

A curable resin composition according to the present embodiment contains a rubber component (A), a cross-linking component (B) having an epoxy group, an ester-based curing agent (C), and a curing accelerator (D). The curable resin composition may contain a filler (E) as necessary. The curable resin composition according to the present embodiment can be used for formation of a protective layer (coverlay) covering an electric circuit in a printed wiring board, and can be used as an interlayer adhesive in a multilayer printed wiring board, and the like. According to the curable resin composition according to the present embodiment, it is possible to form a cured product (a protective layer, an adhesive layer, and the like) having excellent low dielectric properties in a high frequency region while having adhesiveness to an adherend, for example, a material constituting a printed wiring board such as a metal portion of a printed wiring board or a base material. Since the curable resin composition according to the present embodiment contains the rubber component (A), the cured product thereof can have elasticity. Therefore, for example, the curable resin composition according to the present embodiment can be suitably used for formation of a protective layer of a flexible printed wiring board and is suitably used as an interlayer adhesive. Hereinafter, each component that can be contained in the curable resin composition will be described.

### <Rubber Component (A)>

The rubber component (A) can include, for example, at least one rubber selected from a group consisting of acrylic rubber, isoprene rubber, butyl rubber, styrene butadiene rubber, butadiene rubber, styrene butylene styrene rubber, styrene ethylene propylene styrene rubber, styrene ethylene butylene styrene rubber, acrylonitrile butadiene rubber, silicone rubber, urethane rubber, chloroprene rubber, ethylene propylene rubber, fluoro rubber, sulfurized rubber, epichlorohydrin rubber, and chlorinated butyl rubber. From the viewpoints of reducing the influence on the insulation reliability due to moisture absorption and the like, reducing the influence on connection reliability, and reducing the damage to wiring, a rubber component having low gas permeability may be used. From this viewpoint, the rubber component (A) may contain at least one selected from styrene butadiene rubber, butadiene rubber, styrene ethylene butylene styrene rubber, and butyl rubber. The rubber component (A) may contain styrene ethylene butylene styrene rubber.

Examples of commercially available products of acrylic rubber include “Nipol AR series” manufactured by Zeon Corporation and “Kurarity series” manufactured by Kuraray Co., Ltd.

An example of a commercially available product of isoprene rubber includes “Nipol IR Series” manufactured by Zeon Corporation.

An example of a commercially available product of butadiene rubber includes “Nipol BR series” manufactured by Zeon Corporation.

An example of a commercially available product of acrylonitrile butadiene rubber includes “NBR series” manufactured by ENEOS Materials Corporation (formerly: “JSR NBR series” manufactured by JSR Corporation).

An example of a commercially available product of silicone rubber includes “KMP series” manufactured by Shin-Etsu Chemical Co., Ltd.

An example of a commercially available product of ethylene propylene rubber includes “EP Series” manufactured by ENEOS Materials Corporation (formerly: “JSR EP Series” manufactured by JSR Corporation).

An example of a commercially available product of fluoro rubber includes “DAIEL series” manufactured by Daikin Industries, Ltd.

An example of a commercially available product of epichlorohydrin rubber includes “Hydrin series” manufactured by Zeon Corporation.

The rubber component (A) can also be produced by synthesis. For example, acrylic rubber is obtained by reacting (meth) acrylic acid, a (meth) acrylic acid ester, an aromatic vinyl compound, a vinyl cyanide compound, or the like.

The rubber component (A) may contain rubber having a cross-linking group. When rubber having a cross-linking group is used, strength, heat resistance, and adhesiveness of the cured product tend to be improved. The cross-linking group may be any reactive group that can progress the reaction of crosslinking a molecular chain of the rubber component (A). Examples thereof include a reactive group, an acid anhydride group, an amino group, a hydroxyl group, an epoxy group, and a carboxy group which the cross-linking component (B) to be described later has.

The rubber component (A) may contain rubber having at least one cross-linking group of an acid anhydride group and a carboxy group. An example of the rubber having an acid anhydride group includes rubber partially modified with maleic anhydride. The rubber partially modified with maleic anhydride is a polymer containing a constituent unit derived from maleic anhydride. The rubber component (A) may include rubber partially modified with maleic anhydride. An example of a commercially available product of the rubber partially modified with maleic anhydride includes a styrene-based elastomer “TAFPRENE 912” manufactured by Asahi Kasei Corporation.

The rubber partially modified with maleic anhydride may be a hydrogenated styrene elastomer partially modified with maleic anhydride. The hydrogenated styrene elastomer can also be expected to have effects such as improvement in connection reliability, improvement in insulation reliability, and improvement in weather resistance. The hydrogenated styrene elastomer is an elastomer obtained by adding hydrogen to an unsaturated double bond of a styrene elastomer having a soft segment containing an unsaturated double bond. Examples of commercially available products of the hydrogenated styrene elastomer partially modified with maleic anhydride include “FG1901” and “FG1924GT” manufactured by Kraton Polymers Japan Co., Ltd., and “Tuftec M1911”, “Tuftec M1913”, and “Tuftec M1943” manufactured by Asahi Kasei Corporation. The hydrogenated styrene elastomer partially modified with maleic anhydride may be a hydrogenated styrene ethylene butylene styrene elastomer partially modified with maleic anhydride.

The weight average molecular weight of the rubber component (A) may be 20,000 to 200,000, 30,000 to 150,000, or 50,000 to 125000 from the viewpoint of coating film properties and circuit embedding properties. The weight average molecular weight (Mw) herein means a value calculated in terms of standard polystyrene determined by gel permeation chromatography (GPC).

In the curable resin composition, the content of the rubber component (A) is preferably 60 to 95% by mass, more preferably 65 to 90% by mass, and still more preferably 70 to 85% by mass, based on the total amount of the rubber component (A), the cross-linking component (B), and the ester-based curing agent (C). When the content of the rubber component (A) is 60% by mass or more, the rubber component and the cross-linking component tend to be well mixed. When the content of the rubber component (A) is 95% by mass or less, the obtained cured product tends to have particularly excellent properties in terms of adhesiveness, connection reliability, insulation reliability, and heat resistance. The content of the rubber component (A) in the cured product may be within the above range based on the mass of the cured product.

### <Cross-Linking Component (B) Having Epoxy Group>

The cross-linking component (B) having an epoxy group is a component that forms a crosslinked polymer by crosslinking during curing reaction. The cross-linking component (B) having an epoxy group is a component that does not correspond to the rubber component (A). The cross-linking component (B) having an epoxy group is not particularly limited as long as it has an epoxy group in a molecule, and can be, for example, a general epoxy resin. The epoxy resin may be any one of a monofunctional epoxy resin, a bifunctional epoxy resin, and a polyfunctional epoxy resin (trifunctional or higher), and is not particularly limited, but a bifunctional epoxy resin or a polyfunctional epoxy resin may be used from the viewpoint of obtaining more sufficient curability.

Examples of the epoxy resin include epoxy resins of a bisphenol A type, a bisphenol F type, a phenol novolac type, a naphthalene type, a dicyclopentadiene type, a cresol novolac type, and the like. From the viewpoint of low tackiness, dielectric properties, and heat resistance, as the cross-linking component (B) having an epoxy group, a naphthalene type or a dicyclopentadiene type epoxy resin may be selected, or a dicyclopentadiene type epoxy resin may be selected. These epoxy resins can be used singly or in combination of two or more kinds thereof.

By combining rubber having a maleic anhydride group or a carboxy group with a compound having an epoxy group (epoxy resin), particularly excellent effects tend to be obtained from the viewpoint of heat resistance, low moisture permeability, and adhesiveness of the cured product. When heat resistance of the cured product is improved, deterioration in the cured product in a heating step such as nitrogen reflow can be suppressed.

The weight average molecular weight of the cross-linking component (B) having an epoxy group may be, for example, 200 to 2000, but is preferably 200 to 1,000, more preferably 250 to 800, still more preferably 300 to 550, and particularly preferably 350 to 450, from the viewpoints of fluidity of the resin composition and dielectric properties of the cured product.

The number average molecular weight of the cross-linking component (B) having an epoxy group may be, for example, 100 to 1000, but is preferably 150 to 500, more preferably 200 to 400, still more preferably 250 to 350, and particularly preferably 250 to 300, from the viewpoint of fluidity of the resin composition and dielectric properties of the cured product.

The weight average molecular weight (Mw) and the number average molecular weight (Mn) described above mean values calculated in terms of standard polystyrene determined by gel permeation chromatography (GPC).

The epoxy equivalent of the cross-linking component (B) having an epoxy group may be, for example, 200 to 330 g/eq, but may be 220 to 310 g/eq, 220 to 290 g/eq, 220 to 270 g/eq, or 230 to 260 g/eq from the viewpoint of fluidity of the resin composition and dielectric properties of the cured product.

The curable resin composition may contain a cross-linking component other than the cross-linking component (B) having an epoxy group as long as the effect of the present disclosure is not significantly impaired. The content of the other cross-linking component is preferably less than 10 parts by mass with respect to 100 parts by mass of the cross-linking component (B) having an epoxy group from the viewpoint of more sufficiently reducing a dissipation factor of the cured product. <Ester-Based Curing Agent (C)>

An ester-based curing agent (C) itself is a compound involved in a curing reaction, and can reduce a dissipation factor while improving heat resistance of the cured product.

The ester-based curing agent is not particularly limited, but from the viewpoint of more sufficiently obtaining the effect of improving heat resistance and the effect of reducing a dissipation factor, a compound having one or two or more highly reactive ester groups in one molecule, such as phenol esters, esters containing a dicyclopentadiene structure, esters containing a naphthalene structure, thiophenol esters, N-hydroxyamine esters, and esters of heterocyclic hydroxy compounds, is preferably used. As the ester-based curing agent, a compound containing a naphthalene structure may be used. More specific examples of the ester-based curing agent include “EPICLON HPC8000-65 T”, “EPICLON HPC8000-L-65 MT”, “EPICLON HPC8150-60 T”, “EPICLON HPC8150-62 T”, and “EPICLON HPC8150-65 T” (trade names manufactured by DIC Corporation). These can be used singly or in combination of two or more kinds thereof.

It is considered that the ester-based curing agent reacts with the cross-linking component (B) during curing reaction, as shown in the following formula (I). It is considered that a hydroxyl group is not generated in the reaction between the ester-based curing agent (C) and the cross-linking component (B), and a hydroxyl group is hardly generated even if a side reaction occurs, and as a result, a low dissipation factor can be realized.

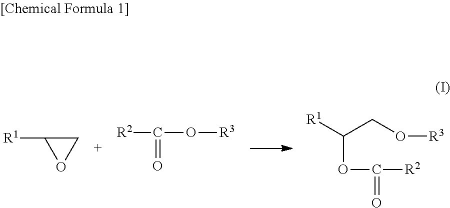

In the formula, R1, R2, and R3 each independently represent a monovalent organic group, but may be a monovalent organic group having an aromatic ring because the effect of the present disclosure can be more sufficiently obtained.

The curable resin composition may contain a curing agent other than the ester-based curing agent (C) as long as the effect of the present disclosure is not significantly impaired. The content of the other curing agent is preferably less than 10 parts by mass with respect to 100 parts by mass of the ester-based curing agent (C) from the viewpoint of more sufficiently reducing the dissipation factor of the cured product.

In the curable resin composition, the total content of the cross-linking component (B) and the ester-based curing agent (C) is preferably 5 to 40% by mass, more preferably 10 to 35% by mass, and still more preferably 15 to 30% by mass, based on the total amount of the rubber component (A), the cross-linking component (B), and the ester-based curing agent (C). When the total content of the cross-linking component (B) and the ester-based curing agent (C) is 5% by mass or more, more sufficient curing is easily obtained, and the cured product tends to have particularly excellent properties in terms of adhesiveness, connection reliability, insulation reliability, and heat resistance. When the total content of the cross-linking component (B) and the ester-based curing agent (C) is 40% by mass or less, the rubber component and the cross-linking component tend to be well mixed with each other, and the cured product tends to have more excellent properties in terms of dielectric properties.

In the curable resin composition, a content ratio between the cross-linking component (B) and the ester-based curing agent (C) is preferably in the range of 4:5 to 5:4, and more preferably in the range of 4.5:5 to 5:4.5 in terms of an equivalent ratio between an epoxy group in the epoxy resin (B) and an ester bond in the ester-based curing agent (C). When the content ratio is within the above range, more sufficient curing is easily obtained, and the cured product tends to have particularly excellent properties in terms of dielectric properties, adhesiveness, insulation reliability, and heat resistance.

### <Curing Accelerator (D)>

The curing accelerator (D) is a compound that functions as a catalyst of a curing reaction. The curing accelerator (D) may be selected from a tertiary amine, an imidazole, an organic acid metal salt, a phosphorus-based compound, a Lewis acid, an amine complex salt, and a phosphine. Among them, imidazole may be used from the viewpoint of storage stability of the varnish of the curable resin composition, curability, and dielectric properties of the cured product. When the rubber component (A) contains a rubber partially modified with maleic anhydride, imidazole compatible therewith may be selected. Imidazole may be 1-benzyl-2 methylimidazole.

In the curable resin composition, the content of the curing accelerator (D) may be 0.1 to 10 parts by mass with respect to 100 parts by mass of the total amount of the rubber component (A), the cross-linking component (B), and the ester-based curing agent (C). When the content of the curing accelerator (D) is 0.1 parts by mass or more, more sufficient curing tends to be easily obtained. When the content of the curing accelerator (D) is 10 parts by mass or less, particularly excellent effects tend to be obtained in terms of storage stability of varnishes, films and the like of the curable resin composition, heat resistance of the cured product, and dielectric properties of the cured product. From the above viewpoint, the content of the curing accelerator (D) may be 0.3 to 7 parts by mass, 0.3 to 5 parts by mass, 0.3 to 2 parts by mass, 0.3 to 1 parts by mass, 0.5 to 5 parts by mass, 0.5 to 2 parts by mass, or 0.5 to 1 parts by mass.

### <Filler (E)>

When the curable resin composition contains the filler (E), the coefficient of thermal expansion (CTE) of the cured product can be reduced.

The filler (E) may be a filler having at least one group selected from a group consisting of a (meth) acryloyl group, a vinyl group, an epoxy group, and a phenylamino group. Having these groups tends to have particularly excellent properties in terms of compatibility with a resin component at a filler interface, dispersibility of a filler, storage stability of a curable resin composition, a coefficient of thermal expansion of a cured product, and adhesiveness of a cured product. Therefore, the curable resin composition can be more suitably used as an interlayer adhesive for a multilayer printed wiring board.

From the viewpoint of the coefficient of thermal expansion and adhesiveness, the filler (E) preferably contains a filler having at least one group selected from a group consisting of a (meth) acryloyl group, a vinyl group, an epoxy group, and a phenylamino group, more preferably contains a filler having at least one group selected from a group consisting of a vinyl group, an epoxy group, and a phenylamino group, and still more preferably contains a filler having an epoxy group.

As the filler (E), a filler having a vinyl group or an epoxy group is further preferable from the viewpoint of the coefficient of thermal expansion and adhesiveness to a low-polarity resin base material, and a filler having an epoxy group is particularly preferable from the same viewpoint. Examples of the low-polarity resin base material include a liquid crystal polymer.

The filler (E) may be a surface-treated filler. The surface-treated filler can be obtained by treating the surface of the filler with a surface treatment agent such as an organic silane compound. Treatment of the surface of the filler tends to have particularly excellent properties in terms of compatibility with the resin component at the filler interface, dispersibility of the filler, storage stability of the curable resin composition, a coefficient of thermal expansion of the cured product, and adhesiveness of the cured product. Therefore, by using the surface-treated filler as the filler (E), the curable resin composition can be more suitably used as an interlayer adhesive of a multilayer printed wiring board. The surface treatment may be surface modification.

From the viewpoint of the coefficient of thermal expansion and adhesiveness, the surface-treated filler preferably contains a filler having at least one group selected from a group consisting of a (meth) acryloyl group, a vinyl group, an epoxy group, and a phenylamino group, more preferably contains a filler having at least one group selected from a group consisting of a vinyl group, an epoxy group, and a phenylamino group, and further preferably contains a filler having an epoxy group.

As the surface-treated filler, a filler having a vinyl group or an epoxy group is further preferable from the viewpoint of the coefficient of thermal expansion and adhesiveness to a low-polarity resin base material, and a filler having an epoxy group is particularly preferable from the same viewpoint. Examples of the low-polarity resin base material include a liquid crystal polymer.

When the surface-treated filler described above is used, the cured product of the curable resin composition tends to be further improved in adhesiveness to a material or the like constituting a printed wiring board, and particularly tends to be further improved in adhesiveness to a base material having a low roughened or non-roughened surface. In the conventional curable resin composition, for example, it is difficult to enhance adhesiveness to a non-roughened liquid crystal polymer film, but the cured product of the curable resin composition containing the surface-treated filler tends to be able to obtain excellent adhesiveness to a low-polarity resin base material, for example, a non-roughened liquid crystal polymer film.

From the viewpoint of achieving both fluidity of the curable resin composition and reduction in the coefficient of thermal expansion of the cured product, the content of the filler (E) may be 30 to 75% by mass, 30 to 70% by mass, 40 to 70% by mass, or 50 to 70% by mass based on the total solid content of the curable resin composition. When the content of the filler (E) is within the above range, both the fluidity of the curable resin composition and the reduction in the coefficient of thermal expansion of the cured product can be achieved.

An average particle diameter of the filler (E) may be 0.01 μm or more, 0.1 μm or more, or 0.2 μm or more, and may be 5.0 μm or less, 4.0 μm or less, 3.0 μm or less, 1.0 μm or less, or 0.8 μm or less from the viewpoint of excellent dielectric properties, adhesiveness, and film appearance of the cured product. That is, the average particle diameter of the filler (E) may be 0.01 to 5.0 μm, 0.1 to 4.0 μm, 0.2 to 3.0 μm, 0.2 to 1.0 μm, or 0.2 to 0.8 μm. The average particle diameter of the filler (E) means a particle diameter at a cumulative frequency of 50% in a particle diameter distribution obtained by a laser diffraction/scattering method.

As the filler (E), an inorganic filler may be used from the viewpoint of further reducing the coefficient of thermal expansion and improving the elastic modulus. An example of the inorganic filler includes a filler containing at least one inorganic substance selected from a group consisting of silica, alumina, titania, tantalum oxide, zirconia, silicon nitride, gallium oxide, boron nitride, barium titanate, barium carbonate, magnesium carbonate, aluminum hydroxide, magnesium hydroxide, lead titanate, lead zirconate titanate, lead lanthanum zirconate titanate, spinel, mullite, cordierite, talc, aluminum titanate, yttria-containing zirconia, barium sulfate, barium silicate, calcium carbonate, calcium sulfate, zinc oxide, and magnesium titanate. The inorganic filler may be used singly or in combination of two or more kinds thereof. Among them, the inorganic filler may be an inorganic filler containing any one of silica, alumina, titania, and boron nitride from the viewpoint of dispersibility and heat resistance of the cured product. The inorganic filler may be an inorganic filler containing silica from the viewpoint of dielectric properties.

As the filler (E), an organic filler may be used. The organic filler is generally particulate and is not dissolved but dispersed in an organic solvent. The organic filler does not correspond to the rubber component (A). An example of the organic filler includes a filler made of liquid crystal polymer (LCP), polytetrafluoroethylene (PTFE), and the like. The organic filler may be used singly or in combination of two or more kinds thereof. As the filler (E), one kind or two or more kinds of inorganic fillers and one kind or two or more kinds of organic fillers may be used in combination.

From the viewpoint of dispersibility and heat resistance, the filler (E) may be an inorganic filler surface-treated with silica, alumina, titania, or boron nitride, or may be an inorganic filler surface-treated with silica, alumina, or boron nitride. The filler (E) may be a surface-treated silica filler obtained by surface-treating silica from the viewpoint of the coefficient of thermal expansion and adhesiveness.

As a surface treatment agent for the inorganic filler, an organic silane compound such as an epoxysilane compound, an aminosilane compound, a (meth) acrylic silane compound, or a vinylsilane compound may be used from the viewpoint of the coefficient of thermal expansion and adhesiveness.

Examples of the organic silane compound include 3-aminopropyltrimethoxysilane, 3-aminopropyltriethoxysilane, 3-(2-aminoethyl) aminopropyltrimethoxysilane, 3-(2-aminoethyl) aminopropylmethyldimethoxysilane, 3-phenylaminopropyltrimethoxysilane, 3-glycidoxypropyltrimethoxysilane, 3-glycidoxypropylmethyldimethoxysilane, 3-glycidoxypropyltriethoxysilane, 3-glycidoxypropylmethyldiethoxysilane, vinyltriacetoxysilane, vinyltrimethoxysilane, vinyltriethoxysilane, vinyltriisopropoxysilane, allyltrimethoxysilane, diallyldimethylsilane, 3-methacryloxypropyltrimethoxysilane, 3-methacryloxypropylmethyldimethoxysilane, 3-methacryloxypropyltriethoxysilane, 3-mercaptopropyltrimethoxysilane, 3-mercaptopropylmethyldimethoxysilane, 3-mercaptopropyltriethoxysilane, N-(1,3-dimethylbutylidene)-3-aminopropyltriethoxysilane, 2-(3,4-epoxycyclohexyl)ethyltrimethoxysilane, tris-(trimethoxysilylpropyl) isocyanurate, and 3-isocyanatopropyltriethoxysilane. <Other Components>

In addition to the above components, if necessary, the curable resin composition may further contain an antioxidant, a yellowing inhibitor, an ultraviolet absorber, a visible light absorber, a colorant, a plasticizer, a stabilizer, a filler, a flame retardant, a leveling agent, and the like as long as the effect of the present disclosure is not significantly impaired.

In particular, the curable resin composition may contain at least one deterioration preventing agent selected from a group consisting of an antioxidant, a heat stabilizer, a light stabilizer, and a hydrolysis inhibitor. The antioxidant suppresses deterioration due to oxidation. The antioxidant imparts sufficient heat resistance at a high temperature to the cured product. The heat stabilizer imparts stability at a high temperature to the cured product. Examples of the light stabilizer include an ultraviolet absorber that prevents deterioration due to ultraviolet rays, a light blocking agent that blocks light, and a quenching agent having a quenching function of receiving light energy absorbed by an organic material to stabilize the organic material. The hydrolysis inhibitor suppresses deterioration due to moisture. The deterioration preventing agent may be at least one selected from a group consisting of an antioxidant, a heat stabilizer, and an ultraviolet absorber. As the deterioration preventing agent, only one of the components exemplified above may be used, or two or more thereof may be used in combination. In order to obtain a more excellent effect, two or more deterioration preventing agents may be used in combination.

The curable resin composition may be prepared as a resin varnish in which each component described above is dissolved or dispersed in an organic solvent. The organic solvent is not particularly limited, and examples thereof include aromatic hydrocarbons such as toluene, xylene, mesitylene, cumene, and p-cymene; cyclic ethers such as tetrahydrofuran and 1,4-dioxane; ketones such as acetone, methyl ethyl ketone (MEK), methyl isobutyl ketone (MIBK), cyclohexanone, and 4-hydroxy-4 methyl-2 pentanone; esters such as methyl acetate, ethyl acetate, butyl acetate, methyl lactate, ethyl lactate, and γ-butyrolactone; carbonic acid esters such as ethylene carbonate and propylene carbonate; and amides such as N, N-dimethylformamide, N, N-dimethylacetamide, and N-methyl-2 pyrrolidone. From the viewpoint of solubility and boiling point, toluene or N, N-dimethylacetamide may be used. These organic solvents can be used singly or in combination of two or more kinds thereof. The solid content (component other than the organic solvent) concentration in the resin varnish may be 20 to 80% by mass.

The mixing and kneading of the resin varnish can be performed by appropriately combining a normal stirrer, a mortar machine, a three-roll mill, a ball mill, or the like.

### [Curable Film and Laminated Film]

A curable film according to the present embodiment includes the curable resin composition described above. The curable film can be easily produced, for example, by applying a resin varnish containing the curable resin composition to a base material film and removing a solvent from a coating film. According to this method, a laminated film including a base material film and a curable film provided on the base material film can be obtained.

The solvent is removed from the coating film on the base material film by drying at a temperature at which the curable resin composition is not cured and under a condition that the solvent is sufficiently volatilized. Specifically, the coating film is dried by heating at usually 60 to 180° C. for 0.1 to 90 minutes. The residual volatile content of the obtained curable film is preferably 10% by mass or less. When the residual volatile content is 10% by mass or less, it is easy to suppress voids from remaining in the cured product due to foaming caused by solvent volatilization during assembly heating. In addition, it is easy to suppress contamination of peripheral materials or members due to volatile components generated during heating.

The material of the base material film is not particularly limited, and examples thereof include polyesters such as polyethylene terephthalate (PET), polybutylene terephthalate, and polyethylene naphthalate; polyolefins such as polyethylene and polypropylene; polycarbonate, polyamide, polyimide, polyamideimide, polyetherimide, polyether sulfide, polyether sulfone, polyether ketone, polyphenylene ether, polyphenylene sulfide, polyarylate, polysulfone, and liquid crystal polymer. Among them, polyethylene terephthalate, polybutylene terephthalate, polyethylene naphthalate, polypropylene, polycarbonate, polyamide, polyimide, polyamideimide, polyphenylene ether, polyphenylene sulfide, polyarylate, and polysulfone are preferable from the viewpoint of flexibility and toughness.

The thickness of the base material film may be appropriately changed depending on intended flexibility, but may be 3 to 250 μm. In general, when the thickness is 3 μm or more, the film strength is sufficient, and when the thickness is 250 μm or less, sufficient flexibility is obtained. From the above viewpoint, the thickness may be 5 to 200 μm or 7 to 150 μm. From the viewpoint of improving peelability from the curable film, a base material film subjected to release treatment with a silicone-based compound, a fluorine-containing compound, or the like may be used as necessary.

If necessary, a protective film may be attached onto the curable film to form a laminated film having a three-layer structure including the base material film, the curable film, and the protective film.

The material of the protective film is not particularly limited, and examples thereof include polyesters such as polyethylene terephthalate, polybutylene terephthalate, and polyethylene naphthalate; and polyolefins such as polyethylene and polypropylene. Among them, from the viewpoint of flexibility and toughness, polyesters such as polyethylene terephthalate; and polyolefins such as polyethylene and polypropylene are preferred. From the viewpoint of improving peelability from the curable film, a protective film subjected to release treatment with a silicone-based compound, a fluorine-containing compound, or the like may be used as necessary.

The thickness of the protective film may be appropriately changed depending on intended flexibility, and may be 10 to 250 μm. In general, when the thickness is 10 μm or more, the film strength is sufficient, and when the thickness is 250 μm or less, sufficient flexibility is obtained. From the above viewpoint, the thickness may be 15 to 200 μm or 20 to 150 μm.

The thickness of the curable film after drying is not particularly limited, and may be usually 5 to 1000 μm. When the thickness is 5 μm or more, the curable film or a cured product thereof tends to easily obtain sufficient strength. When the thickness is 1000 μm or less, drying can be sufficiently performed, so that the amount of the residual solvent in the curable film tends to be easily reduced.

The laminated film can be easily stored, for example, by being wound into a roll shape. Alternatively, a sheet-like laminated film cut out from a roll-shaped film into a suitable size can also be stored.

The curable resin composition, the curable film, and the laminated film according to the present embodiment are suitable for formation of a protective layer (coverlay) covering an electric circuit in a printed wiring board, are suitable as an interlayer adhesive in a multilayer printed wiring board, and are particularly suitable for formation of the protective layer (coverlay).

### [Printed Wiring Board]

The printed wiring board according to the present embodiment includes a laminated body formed of a metal portion forming an electric circuit (conductor circuit) and a resin base material as a constituent element. The printed wiring board can be manufactured, for example, by a conventionally known method such as a subtractive method using a metal-clad laminate. The printed wiring board in the present embodiment is a general term for a so-called flexible printed circuit (FPC), a flat cable, a circuit board for tape automated bonding (TAB), and the like in which a conductor circuit formed of a metal portion is partially or entirely covered with a cover lay film, a screen printing ink, or the like as necessary.

The printed wiring board of the present embodiment can have any laminated configuration that can be adopted as a printed wiring board. For example, a printed wiring board having a base material layer, an adhesive agent layer, a metal portion, and a protective layer can be used.

Further, if necessary, a configuration of a multilayer printed wiring board in which two or three or more of the printed wiring boards are laminated using an interlayer adhesive can be adopted.

In the printed wiring board of the present embodiment, as the base material layer, any base material conventionally used as a base material of the printed wiring board can be used.

In the printed wiring board of the present embodiment, as the base material layer, any resin conventionally used as a base material of the printed wiring board can be used. Examples of the resin of the base material layer include a polyester resin, a polyamide resin, a polyimide resin, a polyamideimide resin, an epoxy resin, a maleimide resin, a liquid crystal polymer, polyphenylene sulfide, syndiotactic polystyrene, a polyolefin-based resin, and a fluorine-based resin (PTFE or the like) such as polytetrafluoroethylene (PTFE).

The curable resin composition of the present embodiment can be used for each adhesive layer, protective layer, and interlayer adhesive of a printed wiring board. In particular, when these layers are formed using the curable resin composition of the present embodiment, for example, the layers have high adhesiveness with a material constituting a printed wiring board, such as a base material layer and a metal portion, and the layers formed using the curable resin composition themselves have excellent low dielectric properties. The cured product of the curable resin composition of the present embodiment has excellent adhesiveness particularly to a low-polarity base material such as a liquid crystal polymer, polyphenylene sulfide, syndiotactic polystyrene, a polyolefin-based resin, or PTFE. Therefore, the curable resin composition of the present embodiment is suitable as a curable resin composition used for a cover lay film, a laminated board, a copper foil with resin, and a bonding sheet. Since the curable resin composition according to the present embodiment contains the rubber component (A), the cured product can have flexibility. Therefore, the curable resin composition according to the present embodiment can be suitably used for formation of a protective layer of a flexible printed wiring board and is suitably used as an interlayer adhesive.

In the printed wiring board of the present embodiment, the metal portion is not particularly limited, but may be copper from the viewpoint of wiring formability. The material for forming copper is not particularly limited, and for example, an electrolytic copper foil and a rolled copper foil used for a copper-clad laminate, a printed wiring board, and the like can be used. Examples of commercially available electrolytic copper foils include F0-WS-18 (trade name, manufactured by Furukawa Electric Co., Ltd.), NC-WS-20 (trade name, manufactured by Furukawa Electric Co., Ltd.), YGP-12 (trade name, manufactured by Nippon Denshi Co., Ltd.), GTS-18 (trade name, manufactured by Furukawa Electric Co., Ltd.), F2-WS-12 (trade name, manufactured by Furukawa Electric Co., Ltd.), and F2-WS-18 (trade name, manufactured by Furukawa Electric Co., Ltd.). Examples of the rolled copper foil include TPC foil (trade name, manufactured by JX Metal Corporation), HA foil (trade name, manufactured by JX Metal Corporation), HA-V2 foil (trade name, manufactured by JX Metal Corporation), and C1100R (trade name, manufactured by Mitsui Sumitomo Metal Mining Brass & Copper Co., Ltd.). From the viewpoint of adhesiveness of the curable resin composition of the present embodiment to a cured product, a copper foil subjected to a roughening treatment may be used. From the viewpoint of folding resistance, a rolled copper foil may be used. The metal portion may have a roughened surface formed by a roughening treatment. When a copper foil subjected to the roughening treatment is used, from the viewpoint of transmission loss, the roughening treatment of the copper foil is preferably minimized, and a copper foil subjected to fine roughening is preferably used. Examples of the finely roughened copper foil include FV (FHG)-WS (trade name: FV-WS/FHG-WS manufactured by Furukawa Electric Co., Ltd. and copper foil product) and FZ-WS (trade name, manufactured by Furukawa Electric Co., Ltd. and copper foil product).

Although the embodiments of the present disclosure have been described in detail above, the present disclosure is not limited to the above embodiments. For example, the curable resin composition described above can be used for the following applications other than the application as a composition for formation of a protective layer (cover lay) or an interlayer adhesive. That is, the curable resin composition can be used for applications such as a primer layer of a hardly adhesive material and an adhesive layer of a low dielectric material with an adhesive layer. A method of applying the curable resin composition is not particularly limited, and for example, application methods such as a comma coater, a bar coater, a die coater, dipping, and spin coating can be used. In addition, the curable film described above can be used for applications such as a build-up film, a resin layer of a resin-attached copper foil, and a low dielectric stretchable base material.

### EXAMPLES

The present disclosure will be described more specifically with reference to the following examples. However, the present disclosure is not limited to these examples.

### Examples 1 to 10 and Comparative Examples 1 and 2

### <Production of Curable Resin Composition>

Respective materials shown in Table 1 were mixed at a solid content ratio (unit: parts by mass) shown in the same table to prepare a curable resin composition. The curable resin composition was prepared so as to have a solid content of 25% by mass by adding toluene as a solvent. Details of the respective materials are shown below.

### Rubber Component (A)

FG1924: maleic anhydride-modified styrene ethylene butylene styrene elastomer (trade name: “FG1924GT” manufactured by Kraton Polymers Japan Co., Ltd.)
   Cross-Linking Component (B) having Epoxy Group
HP7200L: dicyclopentadiene epoxy resin (trade name: “EPICLON HP-7200L” manufactured by DIC Corporation, epoxy equivalent: 247 g/eq, number average molecular weight: 288, and weight average molecular weight: 401)
HP7200: dicyclopentadiene epoxy resin (trade name “EPICLON HP-7200” manufactured by DIC Corporation, epoxy equivalent: 258 g/eq, number average molecular weight: 323, and weight average molecular weight: 504)
HP7200H: dicyclopentadiene epoxy resin (trade name: “EPICLON HP-7200H” manufactured by DIC Corporation, epoxy equivalent: 276 g/eq, number average molecular weight: 435, and weight average molecular weight: 917)
HP7200HHH: dicyclopentadiene epoxy resin (trade name: “EPICLON HP-7200HHH” manufactured by DIC Corporation, epoxy equivalent: 280 g/eq, number average molecular weight: 578, and weight average molecular weight: 1774)

### Ester-Based Curing Agent (C)

HPC8150-62T: ester-based curing agent (trade name: “EPICLON HPC8150-62T” manufactured by DIC Corporation, active ester compound containing naphthalene structure, and toluene solution having solid content of 62% by mass)

### Curing Accelerator (D)

1B2MZ: 1-benzyl-2 methylimidazole (trade name: “1B2MZ” manufactured by Shikoku Chemicals Corporation)

### <Preparation of Laminated Film>

A release-treated polyethylene terephthalate (PET) film (trade name: “Purex A3100” manufactured by Toyobo Co., Ltd. and thickness: 25 μm) was prepared as a base material film. The curable resin composition was applied onto the release-treated surface of the PET film using a knife coater (trade name: “SNC-350” manufactured by Yasui Seiki Co., Ltd.). A coating film was dried by heating in a dryer (trade name: “MSO-80TPS” manufactured by Futaba Kagaku Co., Ltd.) at 80° C. for 15 minutes to form a curable film having a thickness of 30 μm. The release-treated PET film same as the base material film was attached to the formed curable film as a protective film in a direction in which the release-treated surface was on the curable film side, thereby obtaining a laminated film.

### [Measurement of Adhesiveness]

The protective films of the laminated films obtained in the examples and the comparative examples were peeled off, and an electrolytic copper foil (trade name “F2-WS-18” manufactured by Furukawa Electric Co., Ltd. and thickness: 18 μm) (hereinafter, also referred to as “VLP-Cu foil”) having a roughened surface having a surface roughness Rz of 1.8 μm was overlaid on the exposed curable film in a direction in which the roughened surface was on the curable film side. In this state, the VLP-Cu foil was laminated on the curable film using a vacuum pressure type laminator (trade name “V130” manufactured by Nikko Materials Co Ltd.) under the conditions of the pressure of 0.5 MPa, the temperature of 100° C., and the pressurization time of 60 seconds. Subsequently, the base material film was peeled off, the VLP-Cu foil was overlaid on the exposed curable film in a direction in which the roughened surface was on the curable film side, and the VLP-Cu foil was laminated on the curable film under the above conditions. Thereafter, heating was performed at 180° C. for 60 minutes in a dryer (trade name: “MSO-80TPS” manufactured by Futaba Kagaku Co., Ltd.) to obtain a laminate including the VLP-Cu foil, the cured film which was a cured product of the curable film, and the VLP-Cu foil.

A sample for measuring a peel strength having a size of 100 mm in length and 5 mm in width was cut out from the obtained laminate. One surface of the sample on the VLP-Cu foil side was fixed to a glass plate with an epoxy adhesive (trade name: “Araldite Rapid” manufactured by Huntsman Japan KK). The other VLP-Cu foil and the cured film were gripped with a jig, and using Autograph (trade name: “EZ-LX” manufactured by Shimadzu Corporation), a 90-degree peel test in which the cured film was peeled from the VLP-Cu foil fixed to a glass plate under the condition of the tensile speed of 50 mm/min was performed. The measurement results of the obtained peel strength are shown in Table 1. The peel strength of 0.7 kN/m or more is acceptable.

### [Measurement of Relative Permittivity (Dk) and Dissipation Factor (Df)]

The laminated films obtained in the examples and the comparative examples were heated at 180° C. for 60 minutes to cure a curable film, thereby forming a cured film. The base material film and the protective film were removed from the cured film, and the cured film was cut into a size of 60 mm×60 mm, thereby obtaining a test piece. Using this test piece, the relative permittivity (Dk) and the dissipation factor (Df) were calculated by a split post dielectric resonators (SPDR) method. A vector type network analyzer E8364B (manufactured by Keysight Technologies), CP531 (manufactured by Kanto Electronics Application & Development Inc.), and a CPMA-V2 (program) were used as measuring instruments, and measurement was performed under the conditions of an ambient temperature of 25° C. and a frequency of 10 GHz. The results are shown in Table 1.

TABLE 1

| Material | | Example 1 | Example 2 | Example 3 | Example 4 | Example 5 | Example 6 |
|---|---|---|---|---|---|---|---|
| Rubber component (A) | FG1924 | 80 | 80 | 80 | 80 | 80 | 80 |
| Cross-linking component (B) | HP7200L | 10.4 | — | — | — | — | — |
| | HP7200 | — | 10.6 | — | — | — | — |
| | HP7200H | — | — | 10.9 | — | 10.9 | 10.9 |
| | HP7200HHH | — | — | — | 11.3 | — | — |
| Ester-based curing agent (C) | HPC8150-62T | 9.6 | 9.4 | 9.1 | 8.7 | 9.1 | 9.1 |
| Curing accelerator (D) | 1B2MZ | 3 | 3 | 3 | 3 | 4 | 1 |
| 90-degree peel strength (kN/m) | | 4.4 | 3.3 | 4.0 | 4.3 | 3.4 | 3.2 |
| Dielectric properties | Dk | 2.31 | 2.29 | 2.36 | 2.38 | 2.39 | 2.34 |
| | Df | 0.0017 | 0.0019 | 0.0022 | 0.0022 | 0.0022 | 0.0022 |

| | | Example | Example | Example | Example | Comparative | Comparative |
|---|---|---|---|---|---|---|---|
| Material | | 7 | 8 | 9 | 10 | Example 1 | Example 2 |
| Rubber component (A) | FG1924 | 80 | 80 | 80 | 80 | 80 | 80 |
| Cross-linking component (B) | HP7200L | — | 10.4 | 10.4 | 10.4 | 20 | — |
| | HP7200 | — | — | — | — | — | — |
| | HP7200H | 10.9 | — | — | — | — | 20 |
| | HP7200HHH | — | — | — | — | — | — |
| Ester-based curing agent (C) | HPC8150-62T | 9.1 | 9.6 | 9.6 | 9.6 | — | — |
| Curing accelerator (D) | 1B2MZ | 0.5 | 4 | 1 | 0.5 | 0.5 | 0.5 |
| 90-degree peel strength (kN/m) | | 3.1 | 3.4 | 3.1 | 3.3 | 3.5 | 3.2 |
| Dielectric properties | Dk | 2.18 | 2.30 | 2.28 | 2.26 | 2.23 | 2.18 |
| | Df | 0.0020 | 0.0016 | 0.0017 | 0.0017 | 0.0057 | 0.0049 |

1. A curable resin composition comprising: a rubber component (A); a cross-linking component having an epoxy group (B); an ester-based curing agent (C); and a curing accelerator (D).

2. The curable resin composition according to claim 1, wherein the curable resin composition is used for formation of a protective layer covering an electric circuit.

3. The curable resin composition according to claim 1, wherein the cross-linking component (B) having the epoxy group has a weight average molecular weight of 200 to 1000.

4. The curable resin composition according to claim 1, wherein a content of the curing accelerator (D) is 0.1 to 10 parts by mass with respect to 100 parts by mass of a total amount of the rubber component (A), the cross-linking component having the epoxy group (B), and the ester-based curing agent (C).

5. A curable film comprising the curable resin composition according to claim 1.

6. A laminated film comprising: a base material film; and the curable film according to claim 5 provided on the base material film.
